(19) United States
(12) Patent Application Publication
(10) Pub. No.: US 2008/0204132 A1
(43) Pub. Date: Aug. 28, 2008

(54) Class-D Amplifier

(75) Inventors: Franciscus Bernardus Marie Van Horck, Eindhoven (NL); Johannes Gerardus Hendrikus Reekers, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/910,466

(22) PCT Filed: Apr. 10, 2006
(86) PCT No.: PCT/IB06/51088

§ 371 Date: Oct. 2, 2007

(30) Foreign Application Priority Data
Apr. 15, 2005 (EP) 05103020.3

(51) Int. Cl. H03F 3/217

(52) U.S. Cl. 330/10

(57) ABSTRACT

The present invention relates to a class-D amplifier having a pre-processing unit (13). The pre-processing unit is arranged to limit the signal inputted to the amplifier when the amplifier switching frequency drops in order to avoid disturbances occurring when the switching frequency cuts through the amplifier output filter. To this end the amplifier has a comparator (14) that is arranged to compare the signal from the pre-processing unit with the amplifier supply voltage, and means for limiting the gain or increasing the attenuation of the pre-processing unit when the pre-processed signal amplitude exceeds a certain fraction of the supply voltage.

### FIELD OF THE INVENTION

The present invention relates to a closed loop class-D amplifier for amplifying an electric input signal, the amplifier comprising: a pre-processing unit, being capable of changing the amplitude of the input signal to provide a pre-processed signal, a control circuit, arranged to receive the pre-processed signal and a feedback signal, and to generate a control signal, a switching block, arranged to receive said control signal and at least one supply voltage, and to generate, in accordance with the control signal, a block wave signal by alternately switching the block wave signal between first and second states, a low pass filter, arranged to filter the block wave signal to generate an output signal, the feedback signal being depending on the output signal, the pre-processing unit being arranged to limit the pre-processed signal if the frequency of the block wave signal falls below a threshold value.

### BACKGROUND OF THE INVENTION

Such an arrangement is disclosed in U.S. Pat. No. 6,107,875 A. In this arrangement a sensor determines whether the switching block remains in one state longer than a predetermined time, i.e. a measure corresponding to the switching frequency is obtained. If the frequency is too low, the input signal is limited. This avoids the risk that the switching frequency falls to such an extent that it cuts through the output filter and causes a disturbance.

A disadvantage with such an arrangement is that a frequency measurement may be quite complicated.

### SUMMARY OF THE INVENTION

It is therefore an object of the present invention to provide an amplifier of the above-indicated kind, which is less complex.

This object is achieved by a closed loop class-D amplifier as defined in claim 1.

More specifically the pre-processing unit of a class-D amplifier then comprises amplitude changing means, receiving the input signal and generating the pre-processed signal, comparator means, arranged to compare the pre-processed signal with said at least one supply voltage, and regulating means for regulating an amplitude changing function of the amplitude changing means if the amplitude of the instantaneous pre-processed signal exceeds a predetermined proportion of the supply voltage.

This arrangement allows the limiting of the pre-processed signal without actually measuring the frequency. The arrangement can therefore be less complex and thus less expensive.

In an embodiment the amplitude changing means may be an amplifier, and the regulating means may reduce the amplifier gain if the amplitude of the instantaneous pre-processed signal exceeds a predetermined proportion of the supply voltage.

In an alternative embodiment the amplitude changing means may instead be an attenuator, and the regulating means may increase the attenuation of the attenuator if the amplitude of the instantaneous pre-processed signal exceeds a predetermined proportion of the supply voltage.

Preferably, the comparator means comprises an amplifier, arranged to amplify the pre-processed signal, a rectifier circuit, arranged to rectify the amplified pre-processed signal, and a comparator circuit comparing the rectified signal with the supply voltage.

The class-D amplifier may be realized as a full bridge amplifier.

These and other aspects of the invention will be apparent from and elucidated with reference to the embodiments described hereinafter.

### BRIEF DESCRIPTION OF THE DRAWINGS

FIG. 1 illustrates a block diagram of a closed loop class-D amplifier.

FIG. 2a illustrates a schematic embodiment of the amplifier in FIG. 1.

FIG. 2b illustrates a full-bridge configuration corresponding to the embodiment in FIG. 2a.

FIG. 3 illustrates a block diagram of a closed loop class-D amplifier according to an embodiment of the invention.

FIG. 4 illustrates an implementation of blocks shown in FIG. 3

### DESCRIPTION OF PREFERRED EMBODIMENTS

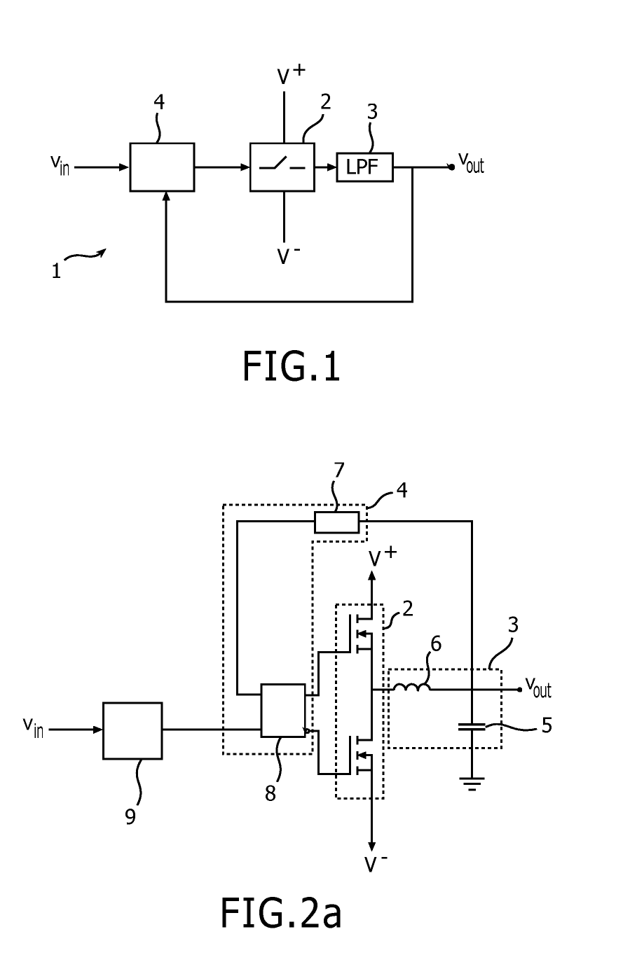

FIG. 1 illustrates a block diagram of a closed loop class-D amplifier. The amplifier 1 receives an input signal vᵢₙ and generates an amplified output signal vₒᵤₜ. The output signal is generated by letting a switching block 2 produce a block wave signal, alternating between first and second states, such as between the supply voltages V⁺ and V⁻, (e.g. V⁺=+60 V and V⁻=−60 V). The block wave signal is filtered by a low-pass filter 3 to generate the output signal vₒᵤₜ. The amplitude of the output signal depends on the pulse ratio of the block wave signal. A control circuit 4 controls the switching block 2 in order to produce an output signal that is an amplified version of the input signal.

In this closed loop configuration, the control circuit receives a feedback signal corresponding to vₒᵤₜ and the input signal vᵢₙ. This configuration is suitable for high power applications, e.g. 150 W.

In contrast, an open loop configuration, mostly used in low power applications, does not need a feedback loop. Instead, the input signal and a constant frequency saw tooth or triangle wave signal are compared, and the output of the comparator is used to control the switching block 2.

A closed loop configuration may use a hysteres function as described in U.S. Pat. No. 6,107,875. As an alternative a configuration using self-oscillation without hysteres effect may be used as disclosed in WO, A2, 03/090343.

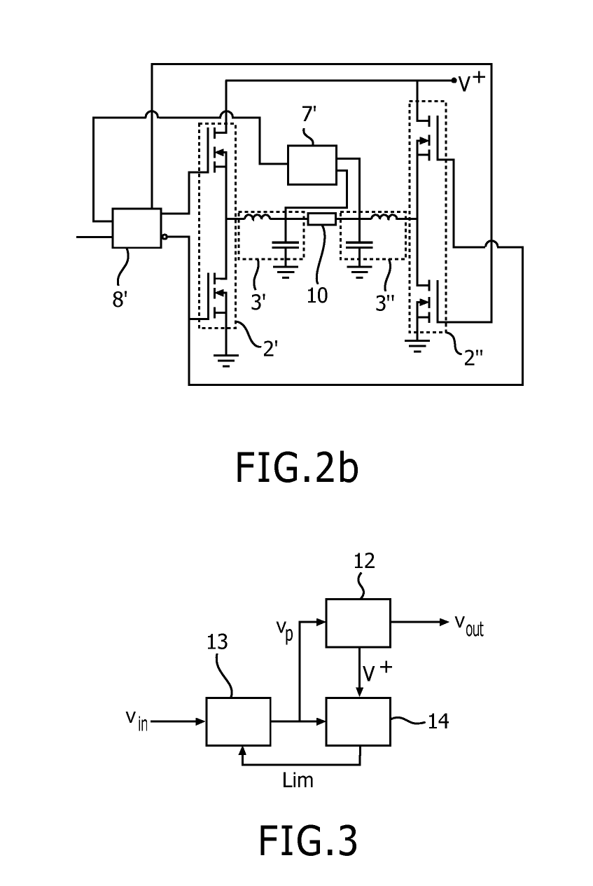

FIG. 2a illustrates an embodiment of the amplifier in FIG. 1. The low-pass filter 3 may consist of a capacitor 5 and an inductor 6. The capacitor 5 and the inductor 6 should have such values, that the filter blocks the block wave switching frequency. The control circuit 4 may comprise a feedback network 7 and a comparator 8. The comparator 8 may have a two complementary outputs, as illustrated, each controlling one switch of a switching block 2. The switches may preferably be MOSFET switches. One switch is connected to a first supply voltage V⁺ and the other to a second supply voltage V⁻. The switches are further connected to each other at a connection point that constitutes the output of the switching block. Since the switches are controlled in a complementary fashion, one of the switches will always be active while the other is blocked. Therefore, the switching block will output either V⁺ or V⁻. A self-oscillating condition may be obtained by providing a sufficient phase shift and delay with the feedback network 7 as is known by the skilled person.

The switching frequency f_{sw} of such a class-D amplifier may be defined as:

f_{sw}=f_{sw0}(1−M²)

where f_{sw0} is the switching frequency near a signal zero crossing (e.g. 400-500 kHz), and M is the modulation index, i.e. the ratio between the output peak voltage and the supply voltage. If the modulation index becomes high, i.e. if the desired instantaneous output voltage comes close to the supply voltage, the switching frequency drops substantially. If the switching frequency falls within the range of the low-pass filter 3, a substantial interfering signal will be outputted through the filter. In an audio application for instance, the filter should remove signal components over 20 kHz. If f_{sw0} is 500 kHz, and the supply voltages V⁺/V⁻ are +/−60 V, an annoying 20 kHz signal will be heard as soon as the instantaneous output signal reaches 58.8 V, even if the frequency of the input signal to be amplified is much lower. Therefore a pre-amplifier 9 may be used that limits the input signal as soon as the switching frequency falls beneath a predetermined frequency, similar to what is described in U.S. Pat. No. 6,107,875.

FIG. 2b illustrates a full-bridge configuration substantially corresponding to the half-bridge embodiment in FIG. 2a. This configuration uses only one supply voltage V⁺. Instead, two switching blocks 2′, 2″ are used. The comparator 8 controls these switching blocks in a complementary fashion, such that, in a first switching state, the output of the first switching block 2′ is connected to earth and the output of the second switching block 2″ is connected to V⁺, whereas, in a second switching state, the output of the second switching block 2″ is connected to earth and the output of the first switching block 2′ is connected to V⁺. Each switching block 2′, 2″ has a low-pass filter 3′, 3″, respectively, and a load 10 is connected between the outputs of these filters. The feedback network 7′ may be common to the switching blocks. A full bridge configuration will have the same problem with high amplitude signals as described above for the half-bridge configuration.

FIG. 3 illustrates a block diagram of a closed loop class-D amplifier according to an embodiment of the invention. The amplifier then comprises a main block 12, comprising the blocks illustrated in FIG. 1, namely the control circuit, the switching block and the low-pass filter. The main block 12 receives a pre-amplified signal vₚ and generates the output signal vₒᵤₜ on the basis thereof. The pre-amplified signal may be generated by a pre-amplifier 13, which receives the input signal vᵢₙ of the class-D amplifier. The pre-amplified signal is also fed to a comparator block 14. The comparator block 14 also receives the supply voltage V⁺ (and/or V⁻) from the main block, and compares the supply voltage with the instantaneous pre-amplified signal received from the pre-amplifier.

If the instantaneous pre-amplified signal exceeds a predetermined percentage of the supply voltage it can be assumed that the desired output voltage vₒᵤₜ would approach the supply voltage V⁺ or V⁻ in such a way that the frequency would drop so that the block wave signal would cut through the low-pass output filter. Therefore, when the instantaneous pre-amplified signal exceeds a predetermined percentage of the supply voltage, the comparator block 14 outputs a limit signal lim that is fed to the pre-amplifier 13 and limits the pre-amplifier gain. Thus, the above-described condition can be avoided without actually measuring the block wave frequency, which allows a simple circuitry to be used as will be illustrated further below. Moreover, the above-described arrangement also compensates for fluctuations in the supply voltage.

As disclosed above, the amplitude of the input signal may be pre-processed by means of a pre-amplifier. It is however also possible to use an attenuator (not shown) for this purpose. Then the comparator block 14 increases the attenuation of the attenuator if the amplitude of the instantaneous pre-processed signal vₚ exceeds a predetermined proportion of the supply voltage. The attenuator and a pre-amplifier may with a common name be called an amplitude changing means.

In general thus the class-D amplifier thus comprises amplitude changing means, receiving an input signal and generating a pre-processed signal. The amplifier further comprises comparator means, arranged to compare the pre-processed signal with a supply voltage, and regulating means for regulating an amplitude changing function (attenuation or gain) of the amplitude changing means if the amplitude of the instantaneous pre-processed signal exceeds a predetermined proportion of the supply voltage.

The comparator means may comprise an amplifier, arranged to amplify the pre-processed signal. The signal thus amplified can then be compared with the supply voltage in a comparator circuit to find out if the pre-processed signal exceeds the predetermined proportion of the supply voltage. As an alternative the supply voltage could instead be divided.

The comparator means may also comprise a rectifier circuit, arranged to rectify the amplified, pre-processed signal, such that the instantaneous pre-processed signal can be compared with a supply voltage regardless of the signal polarity, as will be illustrated in an example below.

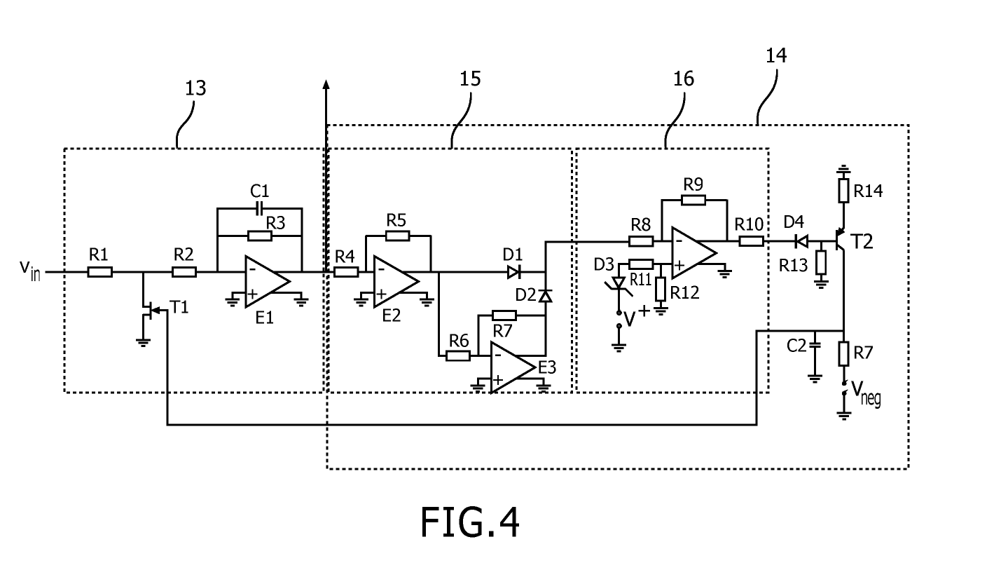

FIG. 4 shows a possible implementation of the pre-amplifier 13 and comparator 14 blocks in FIG. 3. In this configuration the pre-amplifier comprises an operational amplifier arrangement with resistors R1, R2, R3, capacitor C1, and operational amplifier E1. The comparator block 14 comprises a rectifier sub-block 15, a comparator circuit 16 and a limiting signal generating arrangement. The rectifier sub-block 15 comprises an operational amplifier arrangement, comprising resistors R4, R5, and operational amplifier E2, which amplifies the pre-amplified signal vₚ. The rectifier sub-block 15 further comprises an operational amplifier based rectifier arrangement, comprising resistors R6, R7, operational amplifier E3, and diodes D1, D2, receiving the amplified signal. The rectified signal thus generated is fed to the comparator block 16, comprising an operational amplifier based comparator circuit, comprising resistors R8, R9, R10, R11, R12, operational amplifier E4, and zener diode D3, receiving at different inputs the signal outputted from the rectifier sub-block 15 as well as the supply voltage V⁺.

The limiting signal generating arrangement comprises resistors R7, R13 and R14, diode D4, capacitor C2, transistor T2 and a negative voltage supply V_{neg}.

If the instantaneous pre-amplified signal vₚ, rectified and amplified by the rectifier sub-block 15, is larger than the supply voltage V+, the output of operational amplifier E4 goes negative and begins to draw a current through diode D4. Transistor T2 becomes conducting such that a current flows through R7. The JFET transistor T1 in the pre-amplifier block 13 begins to conduct and the pre-amplified signal vₚ is limited. When the voltage drop across R7 is equal to V_{neg}, the JFET transistor T1 is fully conducting and the pre-amplified signal vₚ has its maximum attenuation.

Of course, other implementations are possible.

In summary, the invention relates to a class-D amplifier having a pre-processing unit. The pre-processing unit is arranged to limit the signal inputted to the amplifier when the amplifier switching frequency drops in order to avoid disturbances occurring when the switching frequency cuts through the amplifier output filter. To this end the amplifier has a comparator that is arranged to compare the signal from the pre-processing unit with the amplifier supply voltage, and means for limiting the gain or increasing the attenuation of the pre-processing unit when the pre-processed signal amplitude exceeds a certain fraction of the supply voltage.

The invention is not restricted to the described embodiments. It can be altered in different ways within the scope of the appended claims.

1. A closed loop class-D amplifier for amplifying an electric input signal (vᵢₙ), the amplifier comprising:
a pre-processing unit (9), being capable of changing the amplitude of the input signal (Vᵢₙ) to provide a pre-processed signal (Vₚ),
a control circuit (4), arranged to receive the pre-processed signal (vₚ) and a feedback signal, and to generate a control signal,
a switching block (2, 2′, 2″), arranged to receive said control signal and at least one supply voltage (V⁺, V⁻), and to generate, in accordance with the control signal, a block wave signal by alternately switching the block wave signal between first and second states,
a low pass filter (3), arranged to filter the block wave signal to generate an output signal (vₒᵤₜ), the feedback signal being depending on the output signal (vₒᵤₜ),
the pre-processing unit (9), being arranged to limit the pre-processed signal (vₚ) if the frequency of the block wave signal falls below a threshold value, wherein
said pre-processing unit comprises:
amplitude changing means (13), receiving the input signal (vᵢₙ) and generating the pre-processed signal (vₚ),
comparator means (14), arranged to compare the pre-processed signal (vₚ) with said at least one supply voltage, and
regulating means for regulating an amplitude changing function of said amplitude changing means if the amplitude of the instantaneous pre-processed signal (Vₚ) exceeds a predetermined proportion of the supply voltage.

2. A closed loop class-D amplifier according to claim 1, wherein said amplitude changing means is an amplifier, and said regulating means reduces the amplifier gain if the amplitude of the instantaneous pre-processed signal (vₚ) exceeds a predetermined proportion of the supply voltage.

3. A closed loop class-D amplifier according to claim 1, wherein said amplitude changing means is an attenuator, and said regulating means increases the attenuation of the attenuator if the amplitude of the instantaneous pre-processed signal (vₚ) exceeds a predetermined proportion of the supply voltage.

4. A closed loop class-D amplifier according to claim 1, wherein the comparator means (14) comprises an amplifier, arranged to amplify the pre-processed signal (vₚ), a rectifier circuit, arranged to rectify the amplified, pre-processed signal, and a comparator circuit comparing the rectified signal with the supply voltage.

5. A closed loop class-D amplifier according to claim 1, wherein the class-D amplifier is a full bridge amplifier.
